(19) United States
(12) Patent Application Publication
(10) Pub. No.: US 2025/0370370 A1
(43) Pub. Date: Dec. 4, 2025

(54) METHOD FOR PRODUCING EXPOSING UNIT

(71) Applicant: CANON KABUSHIKI KAISHA, Tokyo (JP)

(72) Inventor: SHINGO IWAMI, Tokyo (JP)

(21) Appl. No.: 19/204,756

(22) Filed: May 12, 2025

(30) Foreign Application Priority Data
May 30, 2024 (JP) 2024-088321

(51) Int. Cl. G03G 15/04; H10K 59/80; H10K 71/40

(52) U.S. Cl. CPC G03G 15/0409; G03G 15/04054; H10K 59/879; H10K 71/421

(57) ABSTRACT

The exposing unit includes a substrate, a plurality of light emitting elements provided on the substrate, a lens array configured to condense light emitted from the plurality of light emitting elements on an irradiated surface, and a holding member configured to hold the substrate and the lens array. A method for producing an exposing unit includes fixing the substrate to the holding member, and fixing the lens array to the holding member after the substrate is fixed to the holding member.

### BACKGROUND

### Field of the Technology

The present disclosure relates to a method for producing an exposing unit that exposes an irradiated surface such as a surface of a photosensitive member.

### Description of the Related Art

As an electrophotographic image forming apparatus, there has been widely used an apparatus that forms an electrostatic latent image on a surface of a photosensitive member by exposing the surface of the photosensitive member from an exposing unit including an LED array as a plurality of light emitting elements and a lens array, and develops a toner image by attaching a toner to the electrostatic latent image (for example, Japanese Patent Application Publication No. 2020-62853).

In such an exposing unit, the substrate on which the LED array is mounted and the lens array are bonded to the holding member via an adhesive or the like. The assembly of the exposing unit is performed by fixing the substrate and the lens array to the holding member while adjusting the positions of the substrate on which the LED array is mounted and the lens array, for example, using a tool so that the optical characteristics satisfy a predetermined standard.

For example, Japanese Patent Application Publication No. 2016-49713 discloses a producing method in which a substrate is fixed after a lens array is fixed to a holding member. In Japanese Patent Application Publication No. 2016-49713, electrode pads capable of passing electricity to the LED array are formed on the substrate, and after the lens array is fixed to the holding member, in a state where the substrate is held by a tool, the substrate is positioned with respect to the holding member while passing electricity to the LED array via the electrode pads. At this time, light emitted from the LED array toward the lens array is received by a camera to position the substrate. Thereafter, the substrate and the holding member are fixed to each other by an adhesive.

In the producing method described in Japanese Patent Application Publication No. 2016-49713, the lens array is first fixed to the holding member, and then the substrate is fixed to the holding member. For this reason, it is necessary to connect an electrical contact tool to electrode pads in order to cause the LED array of the substrate to emit light at the time of adjusting the position of the substrate. Therefore, in Japanese Patent Application Publication No. 2016-49713, it is necessary to fix the substrate to the holding member using an adhesive while adjusting the position of the substrate in a state where the electrical contact tool and the electrode pads of the substrate are connected, which leads to a complicated producing apparatus.

### SUMMARY

The present disclosure provides a producing method capable of fixing a substrate and a lens array to a holding member with high accuracy without complicating a producing apparatus.

According to one aspect of the present disclosure, a method for producing an exposing unit including a substrate, a plurality of light emitting elements provided on the substrate, a lens array configured to condense light emitted from the plurality of light emitting elements on an irradiated surface, and a holding member configured to hold the substrate and the lens array. The method includes fixing the substrate to the holding member, and, fixing the lens array to the holding member after the substrate is fixed to the holding member.

Features of the present disclosure will become apparent from the following description of embodiments with reference to the attached drawings. The following description of embodiments are described by way of example.

### BRIEF DESCRIPTION OF THE DRAWINGS

FIG. 1 is a cross-sectional view illustrating a schematic configuration of an image forming apparatus according to an embodiment.

FIG. 2 is a cross-sectional view of an exposure head according to the embodiment.

FIG. 3 is a perspective view of the exposure head according to the embodiment.

FIG. 4A is a perspective view of the exposure head and a photosensitive drum according to the embodiment.

FIG. 4B is a cross-sectional view of the exposure head and the photosensitive drum according to the embodiment.

FIG. 5A is a perspective view of a substrate according to the embodiment.

FIG. 5B is a plan view of the substrate according to the embodiment.

FIG. 5C is an enlarged plan view illustrating a part of FIG. 5B.

FIG. 5D is a plan view of a lens array according to the embodiment.

FIG. 5E is a perspective view of a schematic configuration of the lens array according to the embodiment.

FIG. 6 is a plan view schematically illustrating a surface of the substrate on which check pads are mounted according to the embodiment.

FIG. 7A is a cross-sectional view of a schematic configuration illustrating a state in which a lens array is assembled to a casing according to a comparative example.

FIG. 7B is a cross-sectional view of a schematic configuration illustrating a state in which a position of the lens array is adjusted with respect to the casing according to the comparative example.

FIG. 8A is a cross-sectional view of a schematic configuration illustrating a state in which an adhesive is applied between the lens array and the casing according to the comparative example.

FIG. 8B is a cross-sectional view of a schematic configuration illustrating a state in which the adhesive applied between the lens array and the casing is irradiated with UV according to the comparative example.

FIG. 8C is a cross-sectional view of a schematic configuration illustrating a state in which the lens array is fixed to the casing according to the comparative example.

FIG. 9A is a schematic view illustrating a state in which a substrate is held by suction pads according to the comparative example.

FIG. 9B is a schematic view illustrating a state in which warpage of the substrate is corrected by the suction pads according to the comparative example.

FIG. 10A is a cross-sectional view of a schematic configuration illustrating a state in which a position of the substrate is adjusted with respect to the casing according to the comparative example.

FIG. 10B is a cross-sectional view of a schematic configuration illustrating a state in which an adhesive is applied between the substrate and the casing according to the comparative example.

FIG. 10C is a cross-sectional view of a schematic configuration illustrating a state in which the adhesive applied between the substrate and the casing is irradiated with UV according to the comparative example.

FIG. 10D is a cross-sectional view of a schematic configuration illustrating a state in which the substrate is fixed to the casing according to the comparative example.

FIG. 11 is a flowchart illustrating a procedure of a method of producing an exposure head according to the embodiment.

FIG. 12A is a schematic view illustrating a state in which a substrate is held by suction pads according to the embodiment.

FIG. 12B is a schematic view illustrating a state in which warpage of the substrate is corrected by the suction pads according to the embodiment.

FIG. 13A is a cross-sectional view of a schematic configuration illustrating a state in which a position of the substrate is adjusted with respect to a casing according to the embodiment.

FIG. 13B is a cross-sectional view of a schematic configuration illustrating a state in which an adhesive is applied between the substrate and the casing according to the embodiment.

FIG. 13C is a cross-sectional view of a schematic configuration illustrating a state in which the adhesive applied between the substrate and the casing is irradiated with UV according to the embodiment.

FIG. 13D is a cross-sectional view of a schematic configuration illustrating a state in which the substrate is fixed to the casing according to the embodiment.

FIG. 14A is a cross-sectional view of a schematic configuration illustrating a state in which a lens array is assembled to the casing according to the embodiment.

FIG. 14B is a cross-sectional view of a schematic configuration illustrating a state in which a position of the lens array is adjusted with respect to the casing according to the embodiment.

FIG. 15A is a cross-sectional view of a schematic configuration illustrating a state in which an adhesive is applied between the lens array and the casing according to the embodiment.

FIG. 15B is a cross-sectional view of a schematic configuration illustrating a state in which the adhesive applied between the lens array and the casing is irradiated with UV according to the embodiment.

FIG. 15C is a cross-sectional view of a schematic configuration illustrating a state in which the lens array is fixed to the casing according to the embodiment.

FIG. 16 is a perspective view of a state in which the substrate and the casing are bonded to each other by a thermosetting adhesive, when viewed from the substrate side of the exposure head, according to the embodiment.

FIG. 17 is a perspective view of a state in which the lens array and the casing are bonded to each other by a thermosetting adhesive, when viewed from the lens array side of the exposure head, according to the embodiment.

FIG. 18A is a cross-sectional view of a schematic configuration illustrating a first example of a modification of the exposure head according to the embodiment.

FIG. 18B is a cross-sectional view of a schematic configuration illustrating a second example of a modification of the exposure head according to the embodiment.

FIG. 18C is a cross-sectional view of a schematic configuration illustrating a third example of a modification of the exposure head according to the embodiment.

FIG. 18D is a cross-sectional view of a schematic configuration illustrating a fourth example of a modification of the exposure head according to the embodiment.

### DESCRIPTION OF THE EMBODIMENTS

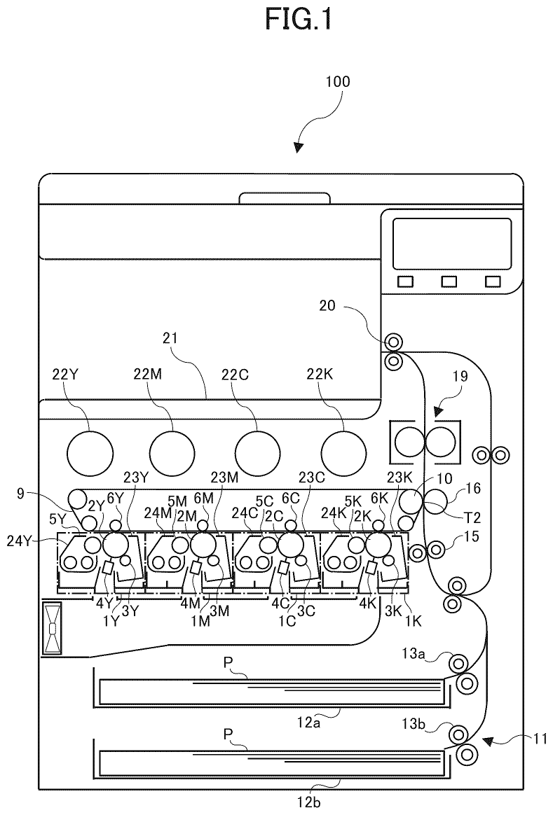

An embodiment will be described with reference to FIGS. 1 to 17. First, a schematic configuration of an image forming apparatus according to the present embodiment will be described with reference to FIG. 1.

### Image Forming Apparatus

FIG. 1 is a schematic cross-sectional view of an image forming apparatus 100. The image forming apparatus 100 is a copying machine including a document reading apparatus, but may be another image forming apparatus such as a printer not including a document reading apparatus in the present embodiment. The present embodiment is not limited to a color image forming apparatus including a plurality of photosensitive drums as illustrated in FIG. 1, and may be a color image forming apparatus including one photosensitive drum or an image forming apparatus that forms a monochrome image.

The image forming apparatus 100 includes four image forming units 1Y, 1M, 1C, and 1K (hereinafter, also collectively and simply referred to as “image forming units 1”) that form toner images of respective colors, yellow, magenta, cyan, and black. The image forming units 1Y, 1M, 1C, and 1K include photosensitive drums 2Y, 2M, 2C, and 2K (hereinafter, also collectively and simply referred to as “photosensitive drums 2”), which are examples of photosensitive members, respectively. The photosensitive drums 2 may be photosensitive belts.

In addition, the image forming units 1Y, 1M, 1C, and 1K include charging rollers 3Y, 3M, 3C, and 3K (hereinafter, also collectively and simply referred to “charging rollers 3”) serving as charging units that charge the photosensitive drums 2Y, 2M, 2C, and 2K, respectively. In addition, the image forming units 1Y, 1M, 1C, and 1K include light emitting diode (hereinafter referred to as LED) exposure heads 4Y, 4M, 4C, and 4K (hereinafter, also collectively and simply referred to as “exposure heads 4”) serving as exposing units that expose the photosensitive drums 2Y, 2M, 2C, and 2K to light.

Further, the image forming units 1Y, 1M, 1C, and 1K include developing units 24Y, 24M, 24C, and 24K (hereinafter, also collectively and simply referred to as a “developing unit 24”) that develop electrostatic latent images on the photosensitive drums 2 with toners and develop toner images of respective colors on the photosensitive drums 2. Note that Y, M, C, and K attached to the reference numerals indicate the colors of the toners.

The image forming apparatus 100 illustrated in FIG. 1 is an image forming apparatus that exposes the photosensitive drums 2 to light from below, that is, employs a so-called “bottom exposure system” in which the exposure heads 4 are disposed below the photosensitive drums 2. The following description will be given on the premise that the image forming apparatus employs a bottom exposure system. Although not illustrated, the image forming apparatus may employ a “top exposure system” in which the photosensitive drum is exposed from above.

The image forming apparatus 100 includes an intermediate transfer belt 9 serving as an intermediate transfer member to which the toner images formed on the photosensitive drums 2 are transferred, and primary transfer rollers 6Y, 6M, 6C, and 6K (hereinafter, also collectively and simply referred to as a “primary transfer roller 6”) that sequentially transfer the toner images formed on the photosensitive drums 2 to the intermediate transfer belt 9. The intermediate transfer belt 9 is disposed above the image forming units 1. Note that, instead of the intermediate transfer method using the intermediate transfer belt 9, a direct transfer method, in which the toner images are transferred from the photosensitive drums 2 to a recording material such as paper, may be used. Examples of the recording material include sheets such as plain paper, thick paper, thin paper, and plastic sheets.

In addition, the image forming apparatus 100 includes a secondary transfer roller 16 serving as a transferring unit that transfers the toner images on the intermediate transfer belt 9 to a recording material P conveyed from a feeding unit 11 in a secondary transfer portion T2, and a fixing unit 19 that fixes the secondarily transferred images to the recording material P. In addition, toner bottles 22Y, 22M, 22C, and 22K (hereinafter, also collectively and simply referred to as “toner bottles 22”) that contain replenishment toners of the respective colors are units that are detachable from the image forming apparatus 100 for replacement. The toner bottles 22 are disposed above the intermediate transfer belt 9. Concerning the toner bottles 22, a toner supply mechanism (not illustrated) supplies an appropriate amount of toner at an appropriate time from each of the toner bottles to a corresponding one of the developing units included in the four image forming units, respectively.

In addition, the image forming apparatus 100 includes a feeding unit 11 that feeds the recording material P. The feeding unit 11 includes sheet cassettes 12a and 12b, feeding rollers 13a and 13b, and a registration roller 15. The sheet cassettes 12a and 12b are disposed below the image forming units 1. The recording materials P accommodated in the sheet cassettes 12a and 12b are fed one by one by the feeding rollers 13a and 13b, and conveyed to the secondary transfer portion T2 at a predetermined timing by the registration roller 15.

### Image Forming Process

Next, an image forming process of the above-described image forming apparatus 100 will be briefly described. The charging roller 3Y charges a surface of the photosensitive drum 2Y. The exposure head 4Y exposes the surface of the photosensitive drum 2Y charged by the charging roller 3Y. As a result, an electrostatic latent image is formed on the photosensitive drum 2Y. Next, the developing unit 24Y develops the electrostatic latent image formed on the photosensitive drum 2Y with the yellow toner. The yellow toner image developed on the surface of the photosensitive drum 2Y is transferred onto the intermediate transfer belt 9 by the primary transfer roller 6Y. The magenta, cyan, and black toner images are also formed by a similar image forming process, and are transferred onto the intermediate transfer belt 9 in a superimposed manner.

The toner images of the respective colors transferred onto the intermediate transfer belt 9 are conveyed to the secondary transfer portion T2 by the intermediate transfer belt 9. The toner images conveyed to the secondary transfer portion T2 are collectively transferred to the recording material P conveyed from the feeding unit 11 by the secondary transfer roller 16. The recording material P to which the toner images have been transferred is conveyed to the fixing unit 19. The fixing unit 19 fixes the toner images onto the recording material P by heat and pressure. The recording material P subjected to the fixing processing by the fixing unit 19 is discharged to a sheet discharge tray 21 disposed above the toner bottles 22 by a sheet discharge roller 20.

### Exposure Head

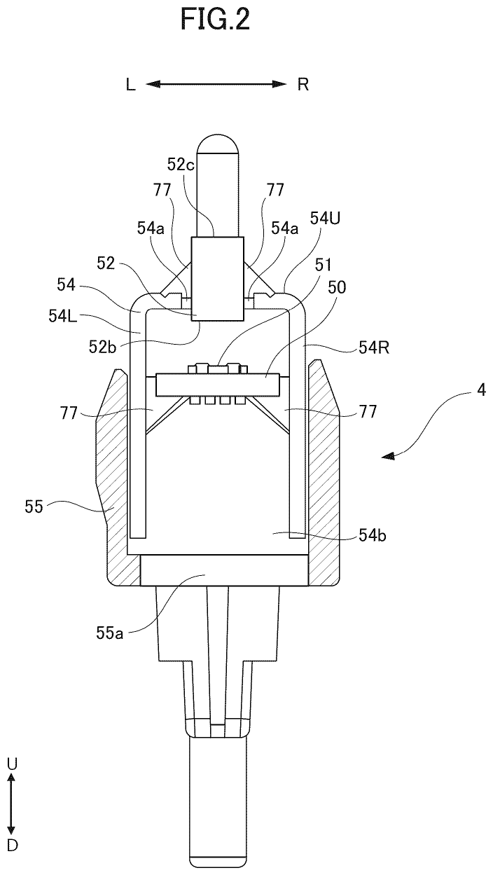

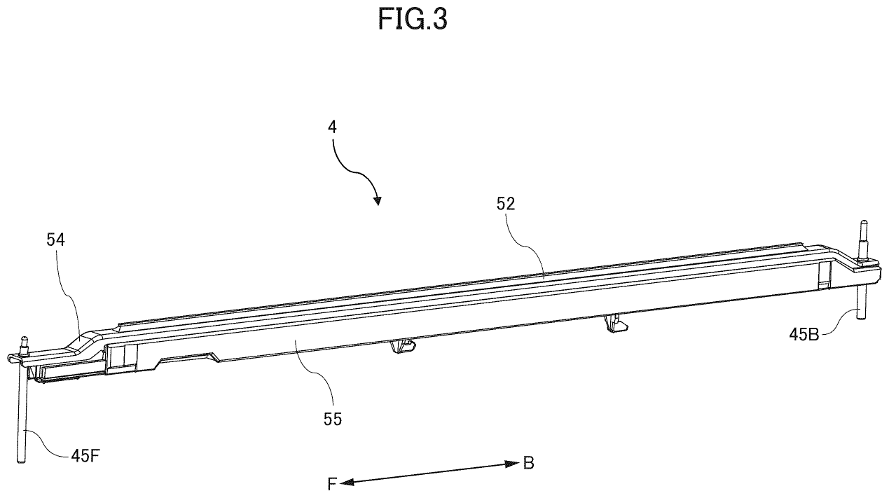

Next, the exposure head 4 serving as an exposing unit will be described with reference to FIGS. 2 and 3. FIG. 2 is a schematic cross-sectional view of the exposure head 4 included in the image forming apparatus 100 according to the present embodiment, and is a view of the exposure head 4 cut in a direction orthogonal to the longitudinal direction. FIG. 3 is a perspective view of the exposure head 4 as viewed from above. The exposure head 4 has an elongated shape (longitudinal shape) extending in the rotation axis direction of the photosensitive drum 2. Specifically, the photosensitive drum 2 is disposed such that its rotation axis direction is a front-rear direction of the image forming apparatus 100 (an F-B direction indicated by an arrow in FIG. 3), and the exposure head 4 is also disposed such that its longitudinal direction is the front-rear direction as illustrated in FIG. 3. Note that the front side (F side) of the image forming apparatus 100 is a side where the apparatus is operated, and for example, is a side where an operation unit such as an operation panel with which the user operates the image forming apparatus 100 is disposed. The back side (B side) of the image forming apparatus 100 is a side opposite to the front side, that is, the rear side of the image forming apparatus 100.

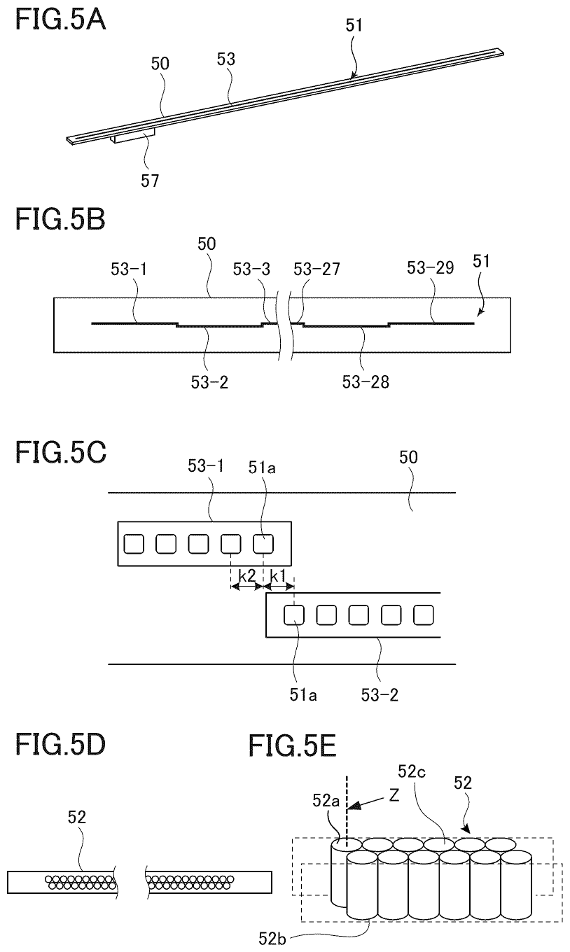

As illustrated in FIG. 2, the exposure head 4 includes a substrate 50, a light emitting element group 51 mounted on the substrate 50, a lens array 52, a casing 54 serving as a holding member that holds the substrate 50 and the lens array 52, and a casing support member 55 that supports the casing 54. As illustrated in FIGS. 5A to 5C to be described below, the light emitting element group 51 is an LED array including a plurality of light emitting diode (LED) chips 53. That is, in the present embodiment, the exposure head 4 includes a plurality of LED chips 53 serving as a plurality of light emitting elements that emit light. Each of the substrate 50, the lens array 52, and the casing 54 has an elongated shape extending in the F-B direction, and the light emitting element group 51 is disposed on the substrate 50 along the F-B direction.

### Positioning of Exposure Head

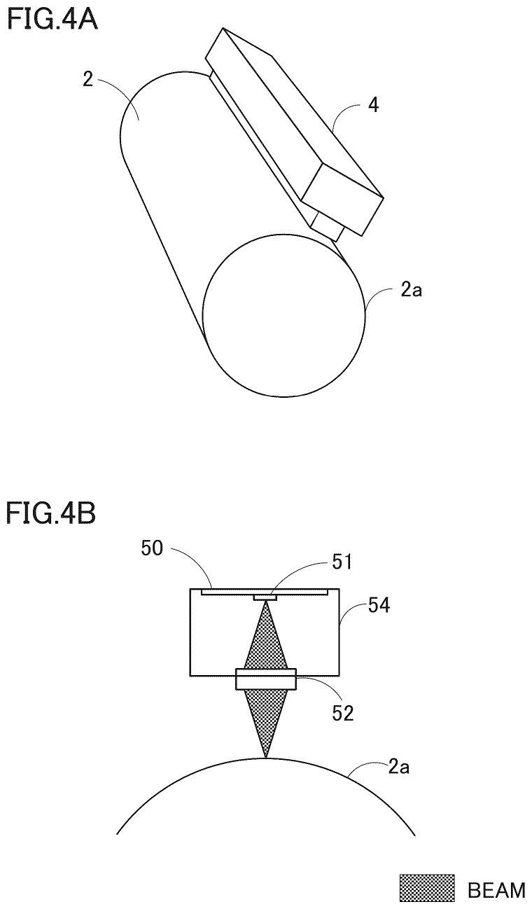

Next, positioning of the exposure head 4 with respect to the photosensitive drum 2 will be described with reference to FIGS. 3, 4A, and 4B. FIG. 4A is a perspective view schematically illustrating a state in which the exposure head 4 is positioned with respect to the photosensitive drum 2. FIG. 4B is a cross-sectional view schematically illustrating a state in which the exposure head 4 is positioned with respect to the photosensitive drum 2. First, positioning pins 45F and 45B of the exposure head 4 will be described. As illustrated in FIG. 3, the casing 54 of the exposure head 4 is provided with positioning pins 45F and 45B that are positioning shafts. The casing 54 is a conductive member having conductivity, and the positioning pins 45F and 45B are also members having conductivity. In the present embodiment, both the positioning pins 45F and 45B are metal pins.

The positioning pins 45F and 45B are fixed to both ends in the longitudinal direction (F-B direction) of the casing 54, respectively. The positioning pin 45F is fixed to the casing 54 on one side (front side) of the lens array 52 in the longitudinal direction (F-B direction), and protrudes from both sides of the casing 54 in the optical axis direction of the lens array 52. The positioning pin 45B is fixed to the casing 54 on the other side (back side) of the lens array 52 in the longitudinal direction (F-B direction), and protrudes from both sides of the casing 54 in the optical axis direction of the lens array 52.

In order to ensure a distance between the surface of the photosensitive drum 2 and the light emitting surface of the lens array 52 of the exposure head 4 with high accuracy, the positioning pins 45F and 45B are caulked to the casing 54 while positions of their positioning surfaces at shaft tips are adjusted with respect to the casing 54. The fixing of the positioning pins 45F and 45B to the casing 54 is not limited thereto, and for example, the positioning pins 45F and 45B made of metal may be fixed to the casing 54 made of metal by welding. In this manner, in the present embodiment, the positioning pins 45F and 45B are integrated with the casing 54.

When the exposure head 4 is positioned with respect to the photosensitive drum 2, the positioning surfaces of the positioning pins 45F and 45B at the shaft tips abut against a bearing that rotatably supports the photosensitive drum 2. As a result, as illustrated in FIGS. 4A and 4B, a gap is formed between the lens array 52 of the exposure head 4 and the photosensitive drum 2. In this way, a distance (gap) between the exposure head 4 and the photosensitive drum 2 is determined in a direction orthogonal to the rotation axis direction of the photosensitive drum 2, and a position of the exposure head 4 with respect to the photosensitive drum 2 is determined. Then, as illustrated in FIG. 4B, light emitted from an LED 51a (see FIG. 5C to be described below) serving as a light emitting element is condensed by the lens array 52 on a surface 2a of the photosensitive drum 2 serving as an irradiated surface.

### Substrate and Lens Array

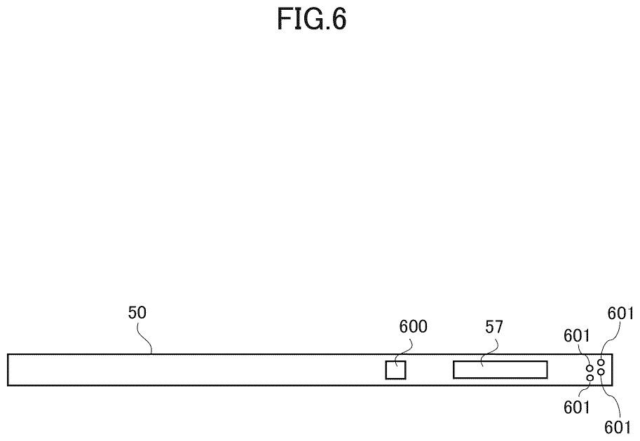

Next, the substrate 50 and the lens array 52 of the exposure head 4 will be described with reference to FIGS. 5A to 5E and FIG. 6. First, the substrate 50 will be described. FIG. 5A is a schematic perspective view of the substrate 50 as viewed from a surface (substrate surface) on which the LED 51a is mounted. FIG. 5B illustrates an arrangement of the plurality of LED chips 53-1 to 53-29 (which may hereinafter be simply referred to as “LED chips 53”) constituting the light emitting element group (LED array) 51 provided on the substrate 50, and FIG. 5C illustrates an enlarged view of FIG. 5B. FIG. 6 is a plan view schematically illustrating a back surface of the substrate 50.

The plurality of LED chips 53 constituting the light emitting element group 51 is mounted on the substrate 50. As illustrated in FIG. 5A, the LED chips 53 are provided on one surface (first surface) of the substrate 50, and an elongated FFC connector 57 is provided on the other surface (second surface) of the substrate 50. The one surface of the substrate 50 mentioned here is a surface (a top surface and a front surface) on a side facing the lens array 52. The other surface of the substrate is a surface (a surface on a side opposite to the side where the LED chips 53 are provided, a bottom surface, and a back surface) opposite to the one surface.

The FFC connector 57 is a connector to which power is supplied from the outside (the apparatus body of the image forming apparatus 100) and which receives a signal when the exposure head 4 is used, and is attached to the other surface of the substrate 50 such that its longitudinal direction is aligned with the longitudinal direction of the substrate 50. The elongated FFC connector 57 is provided on the front side of the image forming apparatus 100 (one side in the longitudinal direction of the substrate 50). Wiring for supplying a signal to each LED chip 53 is provided on the substrate 50. One end of a flexible flat cable (not illustrated, hereinafter FFC) as an example of a cable is connected to the FFC connector 57.

As illustrated in FIG. 6, in addition to the FFC connector 57 described above, check pads 601 serving as electrical contacts and an integrated circuit (IC) 600 are provided on the back surface of the substrate 50. As will be described in detail below, the check pads 601 are electrical contacts electrically connected to the plurality of LED chips 53, and are used at the time of positioning the lens array 52 with respect to the casing 54 or at the time of checking the operation. In the present embodiment, the substrate 50 includes the above-described FFC connector 57 serving as a connector used when the exposure head 4 is used, separately from the check pads 601.

The control circuit unit of the apparatus body of the image forming apparatus 100 is provided with a substrate (not illustrated) including a control unit and a connector. The other end of the FFC is connected to the connector. That is, the FFC electrically connects the substrate (control circuit unit) of the apparatus body and the substrate 50 of the exposure head 4. A control signal (drive signal) is input to the IC 600 of the substrate 50 from the control circuit unit of the apparatus body of the image forming apparatus 100 via the FFC and the FFC connector 57. The control signal is transferred to each LED chip 53. The LED chip 53 is driven (to turn on and off the light) according to the control signal input to the IC 600. Specifically, the FFC connector 57 is connected to the control circuit unit provided in the apparatus body, and receives image data for controlling each LED chip 53 to be turned on and off. The image data input to the FFC connector 57 is converted into a signal suitable for driving each LED chip 53 by the IC 600. In the present embodiment, the image data is input as serial data to the FFC connector 57, converted into parallel data by the IC 600, and then transmitted to each LED chip 53.

The LED chip 53 mounted on the substrate 50 will be described in more detail. As illustrated in FIGS. 5B and 5C, the LED chips 53-1 to 53-29 (29 LED chips), each including a plurality of LEDs 51a (examples of light emitting elements), are arranged on one surface of the substrate 50. In each of the LED chips 53-1 to 53-29, 516 LEDs 51a are arranged in the longitudinal direction thereof. In the longitudinal direction of the LED chip 53, a center-to-center distance K2 between adjacent ones of the LEDs 51a corresponds to a recording resolution of the image forming apparatus 100. Since the recording resolution of the image forming apparatus 100 according to the present embodiment is 1200 dpi, the LEDs 51a are arranged such that the center-to-center distance K2 between adjacent LEDs 51a is 21.16 μm in the longitudinal direction of the LED chips 53-1 to 53-29. Therefore, the exposure head 4 according to the present embodiment has an exposure range of about 314 mm. The photosensitive layer is formed to have a length of 314 mm or more in the rotation axis direction of the photosensitive drum 2. Since the length of the long side of the A4-size recording material and the length of the short side of the A3-size recording material are 297 mm, the exposure head 4 according to the present embodiment has an exposure range capable of forming images on the A4-size recording material and the A3-size recording material.

The LED chips 53-1 to 53-29 are arranged in a staggered manner in the rotation axis direction (main scanning direction) of the photosensitive drum 2. Specifically, the LED chips 53-1 to 53-29 are alternately arranged in two rows along the rotation axis direction of the photosensitive drum 2. That is, as illustrated in FIG. 5B, LED chips 53-1, 53-3, . . . , and 53-29 (odd-numbered columns) odd-numbered when counted from the left side are mounted in a row along the longitudinal direction (main scanning direction) of the substrate 50. In addition, LED chips 53-2, 53-4, . . . , and 53-28 (even-numbered rows) even-numbered when counted from the left side are mounted in a row along the longitudinal direction (main scanning direction) of the substrate 50 at positions shifted in the rotation direction (sub-scanning direction) of the photosensitive drum 2 with respect to the odd-numbered rows.

By arranging the plurality of LED chips 53 in this way, as illustrated in FIG. 5C, a center-to-center distance K1 between the LEDs 51a of different LED chips 53 adjacent in the longitudinal direction of the LED chips 53 arranged at one end of one LED chip 53 and the other end of the other LED chip 53 can be equal to a center-to-center distance K2 between adjacent LEDs 51a on one LED chip 53.

As described above, the light emitting elements according to the present embodiment are semiconductor LEDs, which are light emitting diodes, and in particular, the LEDs 51a are organic light emitting diodes (OLEDs) in the present embodiment. The OLED uses an organic material as a light emitter, and emits light when electricity passes through the light emitter, and the OLED is a current-driven light emitting element that is also called organic electro-luminescence (EL). The OLEDs are arranged on a line along the main scanning direction (the rotation axis direction of the photosensitive drum 2), for example, on a thin film transistor (TFT) substrate, and are electrically connected in parallel by power supply wiring provided along the main scanning direction similarly. The LEDs 51a may be LEDs using an inorganic material as light emitters.

Next, the lens array 52, which is a lens assembly, will be described. FIG. 5D is a schematic view of the lens array 52 as viewed from the photosensitive drum 2 side. FIG. 5E is a schematic perspective view of the lens array 52. As illustrated in FIG. 4B, the lens array 52 condenses light emitted from each LED 51a of the light emitting element group 51 on the surface 2a of the photosensitive drum 2. The lens array 52 is a lens assembly including a plurality of lenses 52a. The plurality of lenses are arranged in two rows along a direction in which the plurality of LEDs 51a are arranged. That is, the plurality of lenses are arranged in two rows in the main scanning direction to correspond to the two rows of LED chips 53 described above.

The lenses 52a are alternately arranged such that one of the lenses 52a in one row is disposed to be in contact with both of the lenses 52a adjacent in a direction in which the lenses 52a in the other row are arranged. Each of the lenses 52a is a cylindrical rod lens made of glass, and has a light incident surface 52b on which light emitted from the LED 51a is incident, and a light emitting surface 52c from which the light incident from the light incident surface 52b is emitted (see FIG. 2). The material of the lens 52a is not limited to glass, and may be plastic. The shape of the lens 52a is not limited to the cylindrical shape, and may be, for example, a polygonal prism such as a hexagonal prism.

A dotted line Z illustrated in FIG. 5E indicates the optical axis of the lens 52a. The optical axis of the lens 52a mentioned here refers to a line connecting the center of the light emitting surface of the lens 52a and the focal point of the lens 52a. The lens array 52 is a lens assembly including a plurality of lenses 52a, and the above-described “optical axis” is an optical axis of any lens 52a among the plurality of lenses 52a. Here, strictly speaking, the plurality of lenses 52a included in the lens array 52 may be slightly inclined with respect to each other. This is due to assembly tolerances. However, deviations within the tolerance range mentioned here are not taken into consideration in defining the direction of the optical axis. Therefore, it is assumed that all of the optical axes of the plurality of lenses 52a are in the same direction. The lens array 52 serves to condense light emitted from the LEDs 51a on the surface 2a of the photosensitive drum 2.

Further, at the time of assembling the exposure head 4, the position at which the lens array 52 is attached to the casing 54 is adjusted so that a distance between the light emitting surfaces of the LEDs 51a and the light incident surfaces of the lenses 52a is substantially equal to a distance between the light emitting surfaces of the lenses 52a and the surface 2a of the photosensitive drum 2.

### Comparative Example

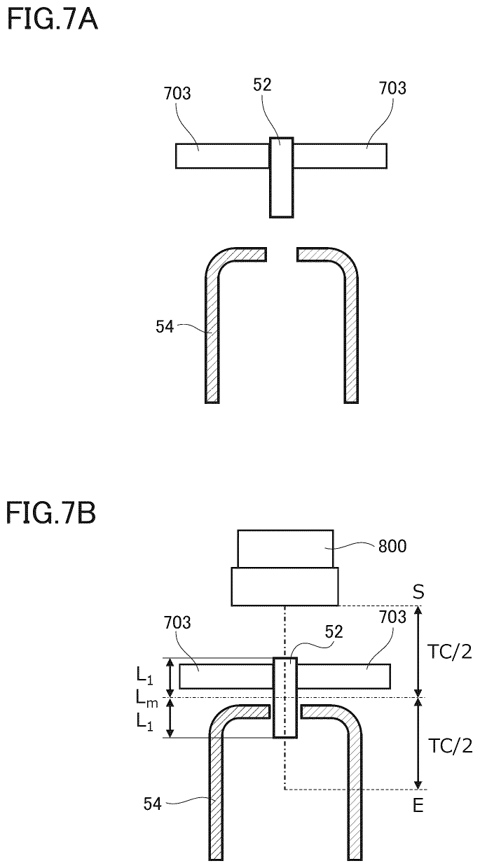

Here, a comparative example of a method for producing the exposure head 4 will be described with reference to FIG. 7A to FIG. 10D. In the comparative example, after the lens array 52 is fixed to the casing 54, the substrate 50 is fixed to the casing 54. As illustrated in FIG. 7A, the lens array 52 held by a lens array holding tool 703 is prepared with respect to the casing 54. Then, as illustrated in FIG. 7B, using a lens array position adjustment camera 800, position adjustment is performed such that a midpoint Lm of the lens array 52 in the optical axis direction coincides with a midpoint of a distance TC between the light emitting surfaces E of the plurality of LED chips 53 provided on the substrate 50 and a position S corresponding to the surface 2a of the photosensitive drum 2 when the exposure head 4 is mounted on the image forming apparatus 100.

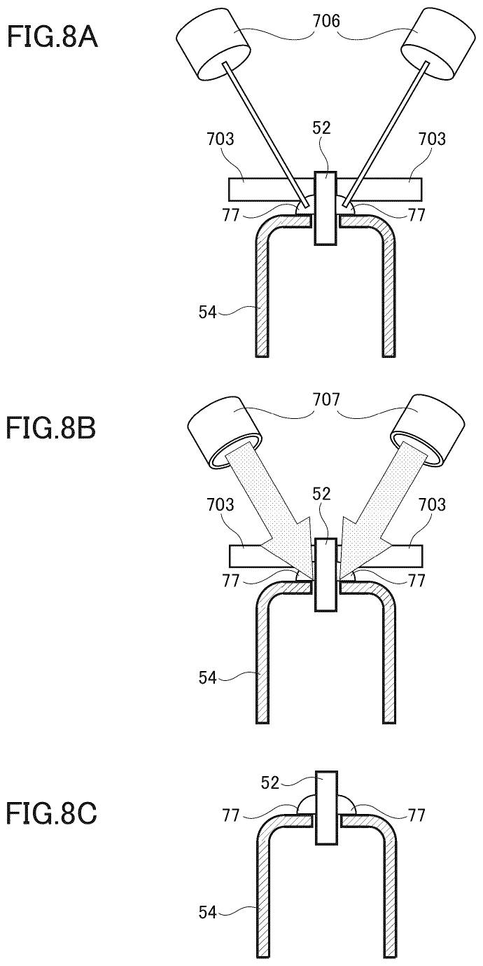

Thereafter, an ultraviolet-curable UV adhesive 77 is applied between the lens array 52 and the casing 54 as illustrated in FIG. 8A, and the UV adhesive 77 is irradiated with ultraviolet (UV) light as illustrated in FIG. 8B, thereby fixing the lens array 52 to the casing 54 as illustrated in FIG. 8C.

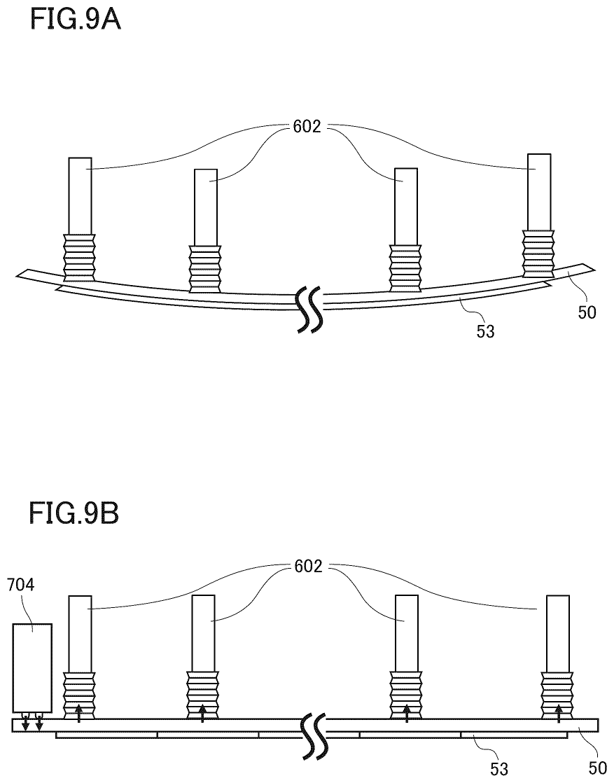

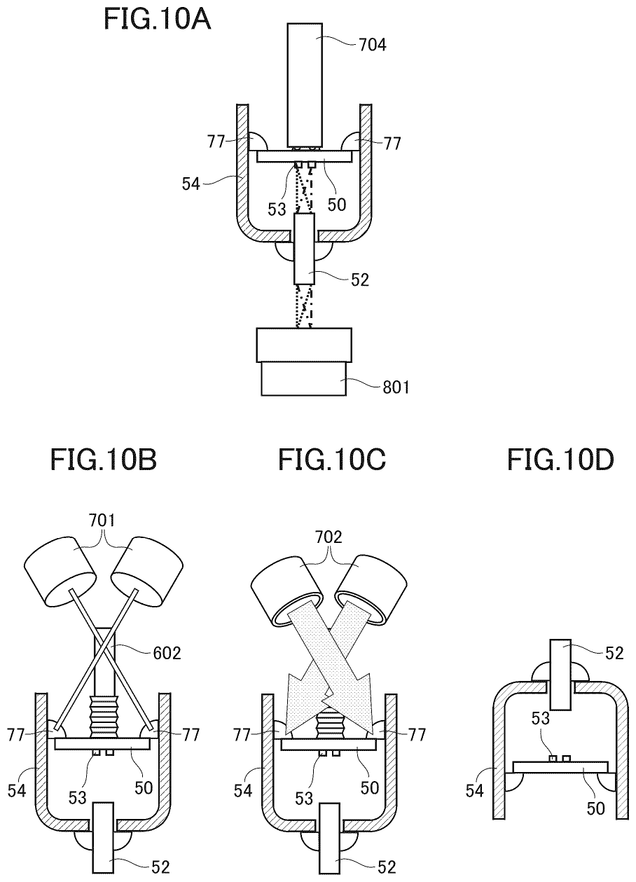

Next, as illustrated in FIG. 9A, the substrate 50 is sucked and held by suction pads 602. Then, as illustrated in FIG. 9B, while the substrate 50 is held by the suction pads 602, electrical contact tool 704 is pressed against the substrate 50 in order to correct the warpage of the substrate 50 and to cause the LEDs 51a to emit light at the time of adjusting the position of the substrate 50 in the next step. While this state is maintained, as illustrated in FIG. 10A, the light emitted from the plurality of LED chips 53 of the substrate 50 to the lens array 52 is received by a substrate position adjustment camera 801. Then, the position of the substrate 50 on which the plurality of LED chips 53 are mounted is adjusted to a position where the imaging characteristics are the best when the plurality of light emitting points arranged in the longitudinal direction on the substrate 50 form an image on the surface 2a of the photosensitive drum 2 through the lens array 52. Thereafter, the UV adhesive 77 is applied between the substrate 50 and the casing 54 as illustrated in FIG. 10B, and the UV adhesive 77 is irradiated with ultraviolet light as illustrated in FIG. 10C, thereby fixing the substrate 50 to the casing 54 as illustrated in FIG. 10D.

In the method of the comparative example described above, when the position of the substrate 50 is adjusted, it is necessary to electrically connect the substrate 50 and the electrical contact tool 704 in order to cause the LEDs 51a provided on the substrate 50 to be adjusted to emit light. In this case, as illustrated in FIG. 9B, since the direction in which the substrate 50 is sucked by the suction pad 602 and the direction in which the substrate 50 is pressed by the electrical contact tool 704 for connection are reversed, which may cause a local deflection of the substrate 50. In addition, since the above-described position adjustment is performed while a space is occupied by a needle for applying the UV adhesive or a UV irradiator, which causes a more complicated producing apparatus.

On the other hand, as another method for electrical connection to the substrate 50, an FFC may be inserted in the same manner as when the image forming apparatus is assembled, or a cable may be inserted into a cable connector other than the FFC connector mounted on the substrate 50. However, in the former method, the number of times of insertion and removal of the FFC increases, and the durability of the substrate 50 may become an issue. For this reason, it is not preferable to insert and remove the FFC many times during producing. In addition, as a common issue between the former method and the latter method, a pulling force or a pushing force of the cable inserted into the substrate 50 may affect the substrate position adjustment. Therefore, both of the two methods may cause a local deflection of the substrate 50, which may result in a deterioration in imaging characteristics of the exposure head 4 with respect to the surface 2a of the photosensitive drum 2.

### Method for Producing Exposing Unit According to Present Embodiment

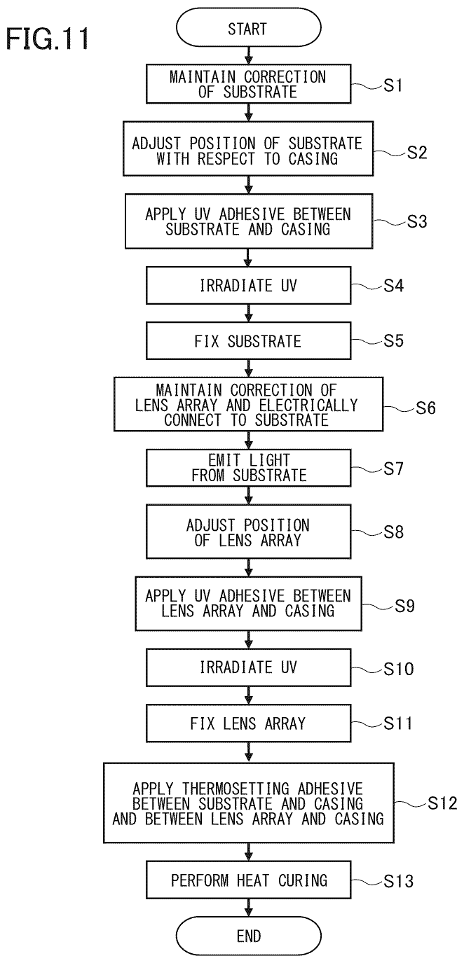

Therefore, in the present embodiment, the exposure head 4 serving as an exposing unit is produced by the following method. The method for producing the exposure head 4 according to the present embodiment will be described with reference to a flowchart of FIG. 11 and FIG. 12A to FIG. 15C. The method for producing the exposure head 4 according to the present embodiment includes a first step of fixing the substrate 50 to the casing 54, and a second step of fixing the lens array 52 to the casing 54 after the first step. That is, in the present embodiment, after the substrate 50, on which the plurality of LED chips 53 are provided, is fixed to the casing 54, the lens array 52 is fixed to the casing 54. The exposure head 4 is produced by a producing device using a robot or the like. In the present embodiment, the substrate 50 and the lens array 52 are fixed to the casing 54 by an adhesive portion where an adhesive is cured.

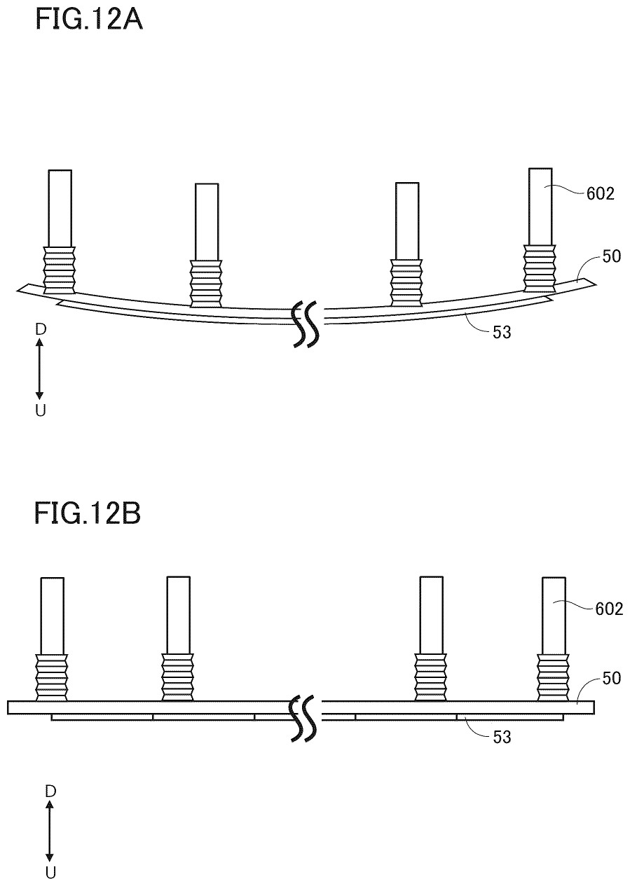

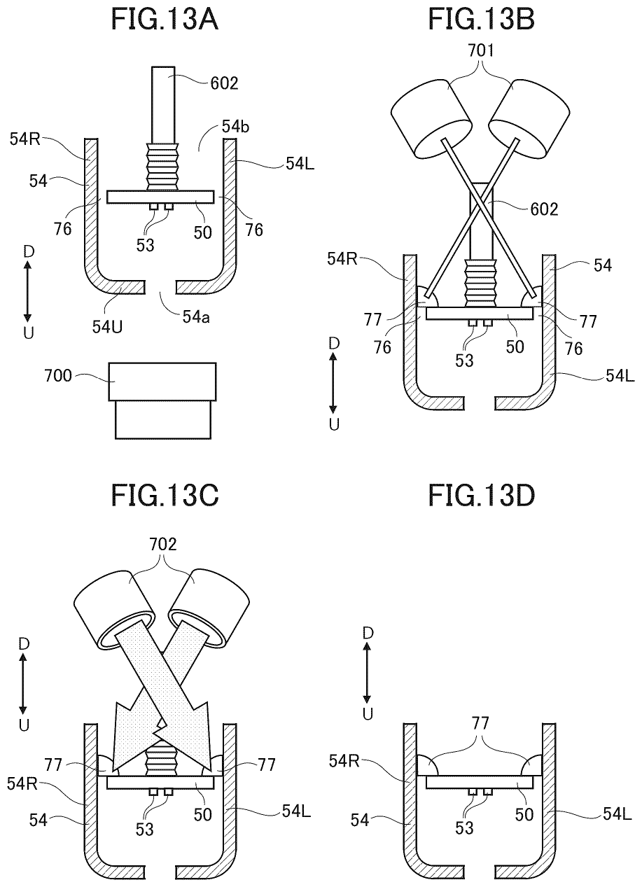

First, after a plurality of locations in the longitudinal direction of the substrate 50 on which the plurality of LED chips 53 are mounted are sucked by the suction pads 602 as illustrated in FIG. 12A, the warpage and deflection of the substrate 50 are corrected as illustrated in FIG. 12B (S1 in FIG. 11). The casing 54 illustrated in FIG. 13A is in a state in which the up-down direction (U-D direction) is reversed from when the exposure head 4 is mounted on the image forming apparatus 100, and is held by a jig (not illustrated). Note that, in the present specification, for convenience, with respect to the optical axis direction of the lens array 52, a side on which light is emitted from the lens array 52 (that is, the light emitting surface 52c side and the upper side in FIG. 2) is defined as an upper side, and a side on which light is incident on the lens array 52 (that is, the light incident surface 52b side and the lower side in FIG. 2) is defined as a lower side. Therefore, the “up-down direction (U-D direction)” used to describe the exposure head 4 in the present specification may be different from the actual up-down direction (vertical direction) when the exposure head 4 is attached to the image forming apparatus 100. The casing 54 is a metal member formed by bending a plate material obtained by plating a galvanized steel plate or a cold-rolled steel plate. In the present embodiment, the casing 54 is formed by pressing a thin sheet metal into a U shape.

The casing 54 has a first opening 54a into which the lens array 52 is inserted, and a second opening 54b into which the substrate 50 is inserted on the opposite side to the first opening 54a side by forming the casing 54 in the U-shape. That is, the casing 54 has an upper plate portion 54U as a first portion in which the first opening 54a is formed, and a pair of bent plate portions 54L and 54R as a pair of second portions extending from both ends of the upper plate portion 54U to the opposite side of the irradiated surface in a direction (an L-R direction indicated by an arrow in FIG. 2 orthogonal to the F-B direction in FIG. 3 and the up-down direction in FIG. 2) orthogonal to the longitudinal direction of the lens array 52. The second opening 54b is a space between the pair of bent plate portions 54L and 54R, and has an opening area larger than that of the first opening 54a. The lens array 52 is fixed to the casing 54 in a state where the lens array 52 has penetrated the first opening 54a, and the substrate 50 is fixed between the pair of bent plate portions 54L and 54R.

As illustrated in FIG. 13A, the substrate 50 inserted from the second opening 54b is subjected to six-axis adjustment such that the positions of the LED chips 53 aligned in the longitudinal direction on the substrate 50 are measured by a substrate position adjustment camera 700 through the first opening 54a, and the positions of the LED chips 53 fall within a predetermined range with respect to the casing 54 in the entire longitudinal direction (S2 in FIG. 11). The six-axis adjustment is a combination of axis-direction adjustment in the X, Y, and Z directions, which are perpendicular to each other, and roll-direction (a yaw direction, a pitch direction and roll direction) adjustment on the respective axes. In the present embodiment, the substrate 50 is positioned with respect to the casing 54 via a gap 76.

While maintaining the position of the substrate 50 adjusted as described above, the ultraviolet-curable UV adhesive 77 is applied between the substrate 50 and the casing 54 by a plurality of UV adhesive applying needles 701 as illustrated in FIG. 13B (S3 in FIG. 11). In the present embodiment, the UV adhesive 77 is applied between the substrate 50 and the casing 54 in a state where the substrate 50 is positioned with respect to the casing 54 via the gap 76.

Next, as illustrated in FIG. 13C, the UV adhesive 77 is irradiated with ultraviolet light from UV lights 702 to cure the adhesive (S4 in FIG. 11). As a result, as illustrated in FIG. 13D, the substrate 50 is fixed to the casing 54 by the UV adhesive 77 (S5 in FIG. 11). That is, in the present embodiment, in the first step, in a state where the substrate 50 is positioned with respect to the casing 54, the UV adhesive 77, which is an ultraviolet-curable adhesive, is applied between the substrate 50 and the casing 54, and the UV adhesive 77 is irradiated with ultraviolet light. As a result, the substrate 50 is fixed to the casing 54.

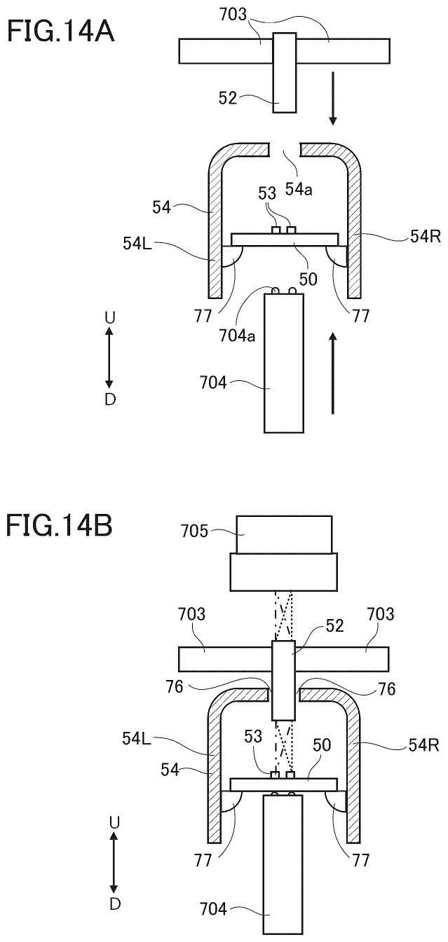

Next, after holding the casing 54 so that its up-down direction is aligned with that when the casing 54 is mounted on the image forming apparatus 100, as illustrated in FIG. 14A, the lens array 52 held by a lens array holding tool 703 is prepared, and the electrical contact tool 704 is pressed against the check pads 601 (FIG. 6) of the substrate 50 to prepare the plurality of LED chips 53 provided on the substrate 50 to be able to emit light (S6 in FIG. 11). As a result, contact probes 704a provided at the tip of the electrical contact tool 704 are pressed against the check pads 601, enabling electrical connection to the plurality of LED chips 53. The check pads 601 are electrical contacts that come into contact with the contact probes 704a in this manner, at the time of assembling the exposure head 4, to supply power for light the plurality of LEDs 51a to the plurality of LED chips 53.

Here, in the present embodiment, as illustrated in FIG. 6, the check pads 601 are disposed at a position not overlapping a region where the LED chips 53 are provided of the substrate 50 in the front-back direction of the substrate 50 (non-overlapping positions). In other words, the check pads 601 are disposed outside the region where the LED chips 53 are mounted of the substrate 50 in the longitudinal direction of the substrate 50. As a result, the pressing force of the contact probes 704a is not generated directly in the region where the LED chips 53 are mounted, making it possible to reduce the influence of the deflection of the substrate 50 caused by the pressing force of the contact probes 704a on the LED chips 53. The electrical contact tool 704 includes wiring for supplying a control signal for controlling light emission of the LED chips 53 and wiring for supplying power for controlling light emission of the LED chips 53.

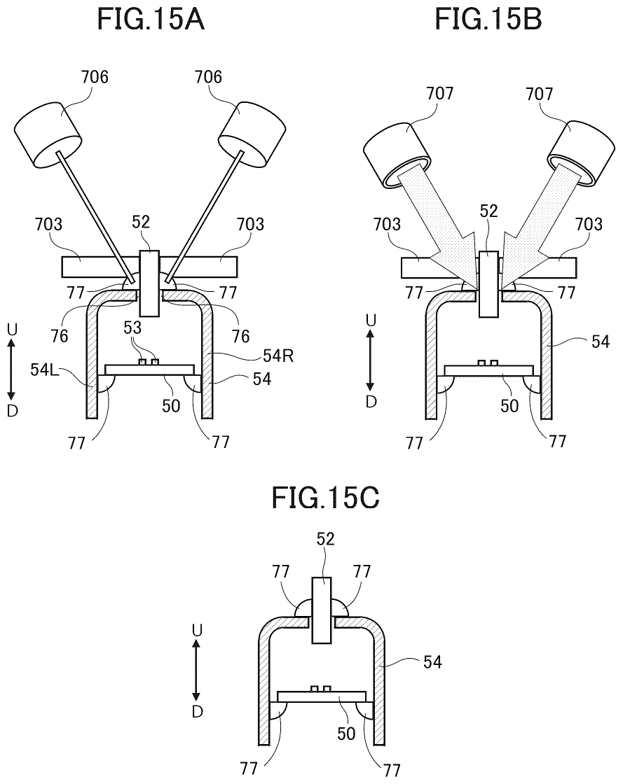

As illustrated in FIG. 14B, the LED chips 53 of the substrate 50 are caused to emit light according to a signal input from the electrical contact tool 704 (S7 in FIG. 11), and the lens array 52 is subjected to six-axis adjustment to a position where the imaging characteristics and the light amount efficiency are the best using a lens array position adjustment camera 705 (S8 in FIG. 11). In the present embodiment, the lens array 52 is positioned with respect to the casing 54 via the gap 76. In a state where the position of the lens array 52 adjusted in this manner is maintained, as illustrated in FIG. 15A, the ultraviolet-curable UV adhesive 77 is applied between the lens array 52 and the casing 54 by a plurality of UV adhesive applying needles 706 (S9 in FIG. 11). In the present embodiment, the UV adhesive 77 is applied between the lens array 52 and the casing 54 in a state where the lens array 52 is positioned with respect to the casing 54 via the gap 76.

Next, as illustrated in FIG. 15B, the UV adhesive 77 is irradiated with ultraviolet light from UV lights 707 to cure the adhesive (S10 in FIG. 11). As a result, as illustrated in FIG. 15C, the lens array 52 is fixed to the casing 54 by the UV adhesive 77 (S11 in FIG. 11).

That is, in the present embodiment, in the second step, after the lens array 52 is positioned with respect to the casing 54 while the plurality of LED chips 53 are caused to emit light by supplying power from the outside (electrical contact tool 704) to the check pads 601, the lens array 52 is fixed to the casing 54. At this time, in a state where the lens array 52 is positioned with respect to the casing 54, the UV adhesive 77, which is an ultraviolet-curable adhesive, is applied between the lens array 52 and the casing 54, and the UV adhesive 77 is irradiated with ultraviolet light. As a result, the lens array 52 is fixed to the casing 54.

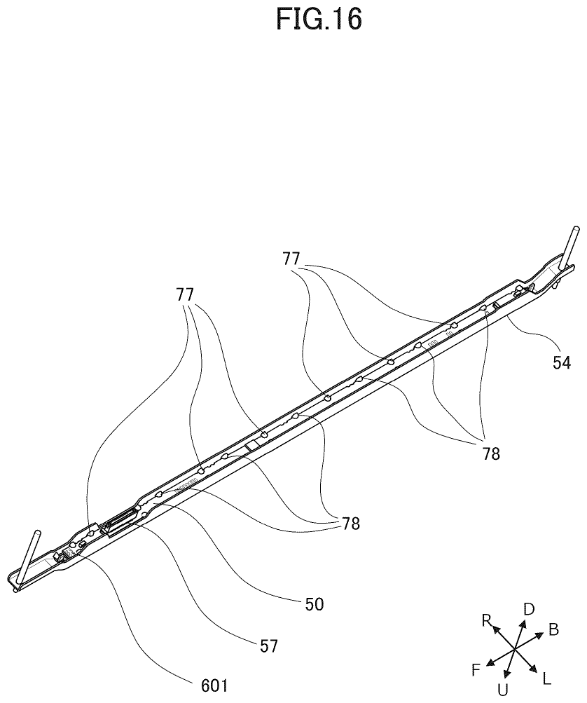

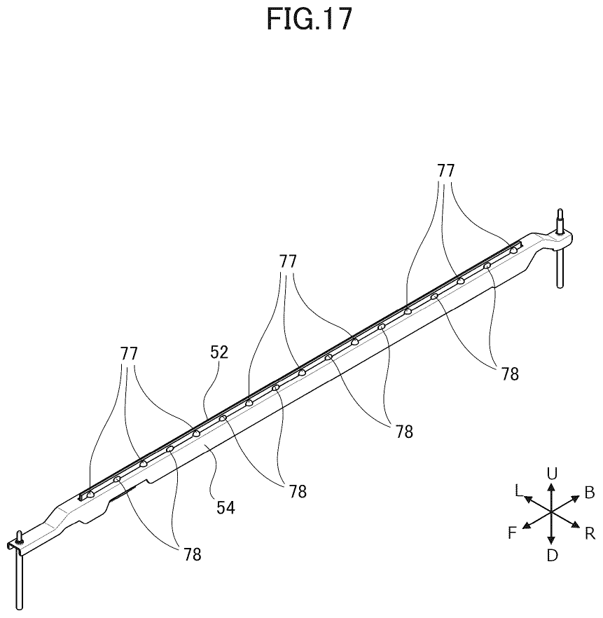

In the present embodiment, after the second step, a thermosetting-type adhesive 78 (hereinafter, also referred to as a “thermosetting adhesive 78”, see FIGS. 16 and 17 to be described below) is applied between the substrate 50 and the casing 54 and between the lens array 52 and the casing 54 (S12 in FIG. 11). Then, the thermosetting adhesive 78 is heated by heating the entire exposure head 4 including the substrate 50, the lens array 52, and the casing 54 (S13 in FIG. 11). As a result, the substrate 50 and the lens array 52 are fixed to the casing 54 by the thermosetting adhesive 78. That is, in the present embodiment, the substrate 50 and the lens array 52 are fixed to the casing 54 by the UV adhesive 77 and the thermosetting adhesive 78.

The fixation of the substrate 50 and the lens array 52 to the casing 54 using two types of adhesives as described above will be described in more detail. The plurality of LED chips 53 provided on the substrate 50 tend to generate heat over time as they emit light, which may cause a rise in the temperature of the entire exposure head 4 including the substrate 50 and the casing 54. At this time, since the substrate 50 and the casing 54 are made of different materials, there is a difference in linear expansion coefficient, which results in a difference in expansion coefficient when the temperature rises. For this reason, when the temperatures of the substrate 50 and the casing 54 rise greatly, there is a possibility that the substrate 50 and casing 54 bonded to each other may be separated from each other due to a difference in thermal expansion coefficient. Therefore, it is desirable that the substrate 50 and the casing 54 be firmly bonded to each other.

Therefore, in the present embodiment, as illustrated in FIG. 16, the substrate 50 and the casing 54 are bonded to each other using a thermosetting-type adhesive (hereinbelow, a thermosetting adhesive) 78 in addition to the UV adhesive 77 described above. FIG. 16 is a perspective view illustrating a configuration in which the substrate 50 and the casing 54 are bonded to each other. The thermosetting adhesive 78 is an adhesive that is cured by applying heat after being applied. In general, the thermosetting adhesive 78 has an excellent hardness after being cured, but often requires a long time to cure. If it takes a long time to bond the substrate 50 and the casing 54, the position of the substrate 50 with respect to the casing 54 may deviate from the design value, and the light source may deviate from the focal position of the lens array 52, which may result in a deterioration in the optical performance of the exposure head 4. Therefore, in the present embodiment, in addition to the thermosetting adhesive 78, the UV adhesive 77 having properties different from those of the thermosetting adhesive is used to bond the substrate 50 and the casing 54 to each other.

As described above, the UV adhesive 77 is an adhesive having a cured property when irradiated with UV light after being applied. The UV adhesive 77 begins to be cured when irradiated with UV light, and thus, is cured faster than the thermosetting adhesive 78. On the other hand, it is desirable that the substrate 50 and the casing 54 are firmly bonded to each other as described above, but the UV adhesive 77 may have an insufficient hardness after being cured to bond the substrate 50 and the casing 54 to each other while being excellent in curing speed.

Therefore, in the method for producing the exposure head 4 in the present embodiment, the substrate 50 and the casing 54 are bonded to each other by the following procedure. First, in a state where the position of the substrate 50 with respect to the casing 54 is defined, the casing 54 and the substrate 50 are fixed to each other by the UV adhesive 77 (S3 to S5 in FIG. 11). After the UV adhesive 77 is cured, the thermosetting adhesive 78 is applied between the substrate 50 and the casing 54 (S12 in FIG. 11). Thereafter, the thermosetting adhesive is cured by applying heat to the entire exposure head 4 (S13 in FIG. 11). The UV adhesive 77 has a sufficient hardness to hold the substrate 50 with respect to the casing 54, and can reduce the possibility that the position of the substrate 50 with respect to the casing 54 is deviated while the thermosetting adhesive 78 is cured.

As described above, in the present embodiment, the substrate 50 and the casing 54 are bonded to each other using a plurality of adhesives having different curing speeds and hardnesses. Accordingly, even when an adhesive having an excellent hardness (the thermosetting adhesive 78 in the present embodiment) takes time to cure, the substrate 50 can be bonded to the casing 54 by an adhesive having an excellent curing speed (the UV adhesive 77 in the present embodiment) without a positional deviation. As a result, the substrate 50 can be firmly fixed to the casing 54 while the position of the substrate 50 with respect to the casing 54 is ensured with high accuracy.

On the other hand, the lens array 52 and the casing 54 also need to be firmly bonded to each other to withstand expansion caused by a rise in temperature. FIG. 17 is a perspective view illustrating a configuration in which the lens array 52 and the casing 54 are bonded to each other. Similarly to the bonding between the substrate 50 and the casing 54 described above, it is also effective to bond the lens array 52 and the casing 54 to each other using a combination of different types of adhesives. For this reason, in the present embodiment, after the casing 54 and the substrate 50 are fixed to each other by the UV adhesive 77 (S3 to S5 in FIG. 11) and the casing 54 and the lens array 52 are fixed to each other by the UV adhesive 77 (S9 to S11 in FIG. 11), the thermosetting adhesive 78 is applied between the substrate 50 and the casing 54 and between the lens array 52 and the casing 54 (S12 in FIG. 11). Then, the thermosetting adhesive 78 is heated by heating the entire exposure head 4 including the substrate 50, the lens array 52, and the casing 54 (S13 in FIG. 11). In this manner, by simultaneously heating the thermosetting adhesive 78 applied between the substrate 50 and the casing 54 and between the lens array 52 and the casing 54, the heating time can be shortened.

According to the present embodiment described above, it is possible to fix the substrate 50 and the lens array 52 to the casing 54 with high accuracy without complicating the producing apparatus. That is, in the present embodiment, as described above, the lens array 52 is fixed to the casing 54 after the substrate 50 is fixed to the casing 54. Therefore, it is not necessary to emit light from the LED chip 53, which needs to be electrically connected at the time of adjusting the position of the substrate 50. Therefore, it is possible to fix the substrate 50 to the casing 54 with high accuracy without complicating the producing apparatus. Further, the substrate 50 can be fixed to the casing 54 without applying stress caused by the electrical contact tool 704 to the substrate 50, enabling high-accuracy producing in terms of optical performance.

When the position of the lens array 52 is adjusted, the LED chips 53 are caused to emit light, and the substrate 50 on which the LED chips 53 are provided is fixed to the casing 54 at this time. Therefore, even though the LED chips 53 are caused to emit light at the time of adjusting the position of the lens array 52, this adjustment can be easily performed, and the lens array 52 can be fixed to the casing 54 with high accuracy.

In the present embodiment, at the time of adjusting the position of the lens array 52, the light emission of the LED chips 53 is performed by pressing the electrical contact tool 704 against the check pads 601 of the substrate 50. The check pads 601 are electrical contacts separate from the FFC connector 57 to which power and signals are supplied when the exposure head 4 is assembled to the image forming apparatus 100 and actually used. Therefore, as compared with a configuration in which the FFC is connected to the FFC connector 57 to cause the LED chips 53 to emit light at the time of adjusting the position of the lens array 52, it is possible to suppress a deterioration in durability of the FFC connector 57 itself or the substrate 50.

In addition, it is conceivable that a connector is provided on the substrate 50 separately from the FFC connector 57, and the FFC is connected to this separate connector at the time of adjusting the position of the lens array 52. However, regardless of whether the FFC is connected to the FFC connector 57 or the separate connector, if the FFC is inserted and removed a plurality of times, a load is applied to the substrate 50, whereby the position of the substrate 50 may deviate or the substrate 50 may be bent. On the other hand, in the present embodiment, since the electrical contact tool 704 is pressed against the check pads 601 to cause the LED chips 53 to emit light at the time of adjusting the position of the lens array 52, it is possible to reduce the load on the substrate 50 at the time of operation, to suppress the positional deviation or deflection of the substrate 50, and to suppress the deterioration in the imaging characteristics of the exposure head 4 with respect to the surface 2a of the photosensitive drum 2 after completion. In particular, in the present embodiment, since the check pads 601 are disposed at a position not overlapping the region where the LED chips 53 are provided in the front-back direction of the substrate 50, it is possible to reduce the influence of the deflection of the substrate 50 caused by the pressing force of the electrical contact tool 704 against the check pads 601 on the LED chips 53, and it is possible to further suppress the deterioration in the imaging characteristics.

### Modification

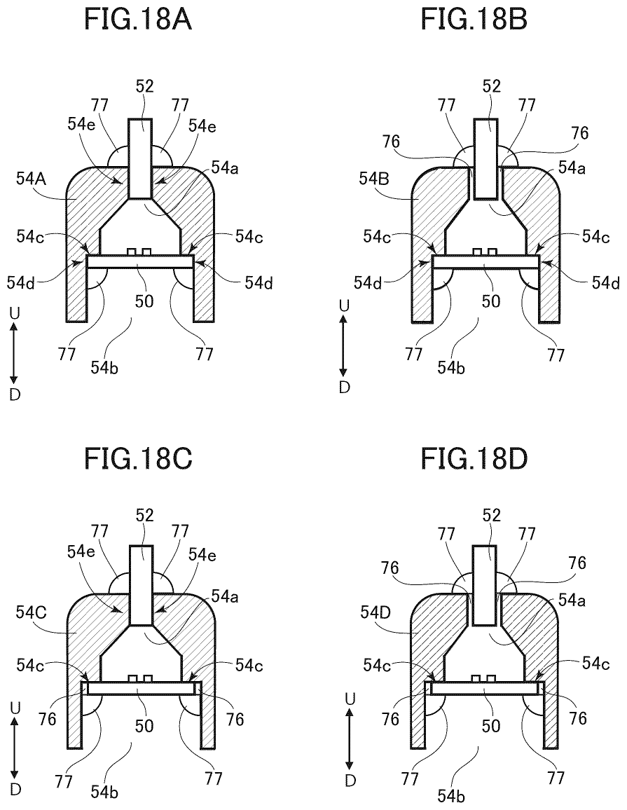

A modification of the present embodiment will be described with reference to FIGS. 18A to 18D. In the above-described embodiment, the substrate 50 and the lens array 52 are positioned with respect to the casing 54 via the gap 76. However, in the modification, at least one of the substrate 50 and the lens array 52 is positioned in contact with a part of a casing 54A, 54B, 54C, or 54D. Then, in this state, the UV adhesive 77 is applied between the substrate 50 and casing 54A, 54B, 54C, or 54D and between the lens array 52 and casing 54A, 54B, 54C, or 54D. In addition, in the above-described embodiment, the casing 54 is formed by bending a sheet metal. However, the casing 54A, 54B, 54C, or 54D in the modification is made of metal with an abutment surface against which the substrate 50 or the lens array 52 abuts being subjected to cutting processing or made of resin with an abutment surface being molded.

In a first example of the modification illustrated in FIG. 18A, the casing 54A includes substrate abutment surfaces 54c and 54d that abut against the substrate 50 and a lens array abutment surface 54e that abuts against the lens array 52. The substrate abutment surface 54c is a surface that positions the substrate 50 in the optical axis direction (the up-down direction in FIG. 18A), and the substrate abutment surface 54d is a surface that positions the substrate 50 in a direction orthogonal to the optical axis direction. The lens array abutment surface 54e is a surface that positions the lens array 52 in a direction orthogonal to the optical axis direction. The same applies to FIGS. 18B to 18D.

In a second example of the modification illustrated in FIG. 18B, the casing 54B has substrate abutment surfaces 54c and 54d that abut against the substrate 50, but a gap 76 exists in a direction orthogonal to the optical axis direction between the lens array 52 and the casing 54B. In a third example of the modification illustrated in FIG. 18C, the casing 54C has a substrate abutment surface 54c that abuts against the substrate 50 and a lens array abutment surface 54e that abuts against the lens array 52. That is, in the third example, a gap 76 is formed between the substrate 50 and the casing 54C in a direction orthogonal to the optical axis direction. In a fourth example of the modification illustrated in FIG. 18D, the casing 54D has a substrate abutment surface 54c that abuts against the substrate 50, and gaps 76 exist in a direction orthogonal to the optical axis direction between the substrate 50 and the casing 54D and between the lens array 52 and the casing 54D. Hereinafter, a difference between the above-described embodiment and the modification will be described.

Difference when Substrate is Assembled

In each of the first and second examples illustrated in FIGS. 18A and 18B, a position of the substrate 50 is determined by the substrate abutment surfaces 54c and 54d of the casing 54A or 54B without performing position adjustment (S2 in FIG. 11) using the substrate position adjustment camera 700. On the other hand, in each of the third and fourth examples illustrated in FIGS. 18C and 18D, a position of the substrate 50 in the optical axis direction is determined by the substrate abutment surface 54c, but a position of the substrate 50 in a direction orthogonal to the optical axis direction is adjusted so that the substrate 50 falls within a predetermined range with respect to the casing 54C or 54D in the entire longitudinal direction similarly to the above-described embodiment (S2 in FIG. 11).

Difference when Lens Array is Assembled

In each of the second and fourth examples illustrated in FIGS. 18B and 18D, since there is no contact portion between the lens array 52 and the casing 54B or 54D, the position of the lens array 52 is adjusted similarly to the above-described embodiment (S8 in FIG. 11). On the other hand, in each of the first and third examples illustrated in FIGS. 18A and 18C, since the positions of the lens array 52 and the casing 54A or 54C in a direction orthogonal to the optical axis direction are determined by the lens array abutment surface 54e, the position adjustment only in the optical axis direction is performed in the entire region in the longitudinal direction (S8 in FIG. 11).

By assembling the substrate 50 and the lens array 52 similarly to the above-described embodiment except for the above-described differences, the substrate 50 and the lens array 52 can be assembled to the casing 54A, 54B, 54C, or 54D with high accuracy without complicating the producing apparatus.

### Other Embodiments

The dimensions, materials, shapes, relative arrangements, and the like of the components described in the above-described embodiment and modification are not intended to limit the scope of the present disclosure only thereto unless otherwise specified, and any configuration may be used as long as the same effect can be obtained. For example, although the UV adhesive that can be cured in a short time is used as an example of the adhesive, but another material may be used, or the check pads are used for electrical connection with the substrate, but another cable connector may be used.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-088321, filed May 30, 2024 which is hereby incorporated by reference herein in its entirety.

What is claimed is:

1. A method for producing an exposing unit including a substrate, a plurality of light emitting elements provided on the substrate, a lens array configured to condense light emitted from the plurality of light emitting elements on an irradiated surface, and a holding member configured to hold the substrate and the lens array, the method comprising:
fixing the substrate to the holding member; and
fixing the lens array to the holding member after the substrate is fixed to the holding member.

2. The method according to claim 1, wherein the substrate includes electrical contacts electrically connected to the plurality of light emitting elements, and
the lens array is fixed to the holding member after positioning the lens array with respect to the holding member while power is supplied from the outside to the electrical contacts to cause the plurality of light emitting elements to emit light.

3. The method according to claim 2, wherein the plurality of light emitting elements are provided on a first surface of the substrate facing the lens array in a state where the substrate and the lens array are held by the holding member, and
the electrical contacts are provided on a second surface of the substrate that is a surface opposite to the first surface.

4. The method according to claim 3, wherein the electrical contacts are disposed at a position not overlapping a region where the plurality of light emitting elements are provided in a front-back direction of the substrate.

5. The method according to claim 3, wherein the fixing the substrate to the includes a connector provided separately from the electrical contacts on the second surface, the connector being configured to receive a signal and to be supplied with power from the outside when the exposing unit is used.

6. The method according to claim 5, wherein the substrate includes an IC configured to transfer the signal received via the connector to the plurality of light emitting elements is provided on the substrate.

7. The method according to claim 1, wherein the light emitting elements are OLEDs.

8. The method according to claim 1, wherein the substrate and the lens array are fixed to the holding member by an adhesive portion where an adhesive is cured.

9. The method according to claim 8, wherein the step of fixing the substrate to the holding member includes
applying an ultraviolet-curable adhesive between the substrate and the holding member in a state where the substrate is positioned with respect to the holding member and,
irradiating the ultraviolet-curable adhesive with ultraviolet light.

10. The method according to claim 9, wherein the step of fixing the lens array to the holding member includes
applying an ultraviolet-curable adhesive is applied between the lens array and the holding member in a state where the lens array is positioned with respect to the holding member,
irradiating the ultraviolet-curable adhesive with ultraviolet light.

11. The method according to claim 10, further comprising:
applying a thermosetting adhesive between the substrate and the holding member and between the lens array and the holding member after the lens array is fixed to the holding member and
heating the thermosetting adhesive.

12. The method according to claim 8, wherein in the step of fixing the substrate to the holding member includes
applying the adhesive between the substrate and the holding member in a state where the substrate is positioned with respect to the holding member via a gap.

13. The method according to claim 8, wherein in the step of fixing the lens array to the holding member includes
applying the adhesive between the lens array and the holding member in a state where the lens array is positioned with respect to the holding member via a gap.

14. The method according to claim 8, wherein in the step of fixing the substrate to the holding member includes
applying the adhesive between the substrate and the holding member in a state where the substrate is positioned with respect to the holding member by coming into contact with a part of the holding member.

15. The method according to claim 8, wherein in the step of fixing the lens array to the holding member includes
applying the adhesive between the lens array and the holding member in a state where the lens array is positioned with respect to the holding member by coming into contact with a part of the holding member.
